(19) United States
(12) Patent Application Publication
(10) Pub. No.: US 2023/0178690 A1
(43) Pub. Date: Jun. 8, 2023

(54) Monolithic LED Array And Method Of Manufacturing Thereof

(71) Applicant: Lumileds LLC, San Jose, CA (US)

(72) Inventors: Grigoriy Basin, San Francisco, CA (US); Mikhail Fouksman, Emerald Hills, CA (US); Norbert Lesch, Vaals (NL)

(73) Assignee: Lumileds LLC, San Jose, CA (US)

(21) Appl. No.: 18/055,969

(22) Filed: Nov. 16, 2022

Related U.S. Application Data
(60) Provisional application No. 63/286,180, filed on Dec. 6, 2021.

(51) Int. Cl. H01L 33/46; H01L 25/075; H01L 33/58

(52) U.S. Cl. CPC H01L 33/46; H01L 25/0753; H01L 33/58; H01L 2933/0025; H01L 2933/0058

(57) ABSTRACT

Described is a light-emitting device and methods of manufacturing thereof. The light-emitting device comprises unpackaged light-emitting diodes arranged in a grid. The unpackaged light-emitting diodes in the are fixed in place by the reflective coating material. Each of the plurality of unpackaged light-emitting diodes are surrounded by a reflective coating material and may be separated by a layer of light absorbing material.

### CROSS-REFERENCE TO RELATED APPLICATIONS

This application claims priority to U.S. Provisional Application No. 63/286,180, filed Dec. 6, 2021, the entire disclosure of which is hereby incorporated by reference herein.

### TECHNICAL FIELD

Embodiments of the disclosure generally relate to light emitting devices and methods of manufacturing the same. More particularly, embodiments are directed to a light emitting diode array that includes unpackaged light-emitting diodes arranged in a grid and fixed in place by a reflective coating material and a light absorbing material.

### BACKGROUND

A light emitting diode (LED) is a semiconductor light source that emits visible light when current flows through it. LEDs combine a P-type semiconductor with an N-type semiconductor. LEDs commonly use a III-group compound semiconductor. A III-group compound semiconductor provides stable operation at a higher temperature than devices that use other semiconductors. The III-group compound is typically formed on a substrate formed of sapphire or silicon carbide (SiC).

For LED arrays used in high brightness applications, side light emission from LEDs needs to be blocked by highly reflective coating. The thickness of reflective side coating and accuracy of LED placement processes necessitate distance of on the order of 500 μm to 600 μm between light emitting areas. Large distance between light emitting areas causes highly visible dark lines in the projected light beam, which interferes with application of the LED array. Additionally, rotational accuracy of LED placement can cause distortion of the projected beam and can reduce maximum intensity of the projected light beam.

Therefore, there is a need for light emitting diode (LED) arrays with minimal dark gaps between light emitting areas.

### SUMMARY

Embodiments of the disclosure are directed to light emitting devices. In an embodiment, a light emitting device comprises: a plurality of unpackaged light-emitting diodes arranged in a grid, each of the unpackaged light-emitting diodes surrounded by a reflective coating material, where each of the unpackaged light-emitting diode of the grid is fixed in place by the reflective coating material.

Embodiments of the disclosure are directed to methods of manufacturing light emitting diode (LED) devices. In one or more embodiments, a method of manufacturing a light emitting diode (LED) device comprises: attaching a plurality of unpackaged light-emitting diodes to a support material; forming a reflective coating material around each of the plurality of unpackaged light-emitting diodes; forming an opening in the reflective coating material between each of the plurality of unpackaged light-emitting diodes, the opening extending through the reflective coating material; depositing a light absorbing material in the opening; and removing the plurality of unpackaged light-emitting diodes from the support material to form a light-emitting diode (LED) array.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments. The embodiments as described herein are illustrated by way of example and not limited in the figures of the accompanying drawings in which like references indicate similar elements.

FIG. 1 illustrates a process flow diagram for a method according to one or more embodiments;

FIG. 2 illustrates a cross-sectional view of a light emitting device according to one or more embodiments;

FIG. 3 illustrates a cross-sectional view of a light emitting device according to one or more embodiments;

FIG. 4 illustrates a cross-sectional view of a light emitting device according to one or more embodiments;

FIG. 5 illustrates a cross-sectional view of a light emitting device according to one or more embodiments;

FIG. 6 illustrates a cross-sectional view of a light emitting device according to one or more embodiments;

FIG. 7 illustrates a cross-sectional view of a light emitting device according to one or more embodiments;

FIG. 8 illustrates a cross-sectional view of a light emitting device according to one or more embodiments;

FIG. 9 illustrates a top plan view of a light emitting device according to one or more embodiments;

FIG. 10 illustrates a process flow diagram for a method according to one or more embodiments;

FIG. 11 illustrates a cross-sectional view of a light emitting device according to one or more embodiments;

FIG. 12 illustrates a cross-sectional view of a light emitting device according to one or more embodiments;

FIG. 13 illustrates a cross-sectional view of a light emitting device according to one or more embodiments;

FIG. 14 illustrates a cross-sectional view of a light emitting device according to one or more embodiments;

FIG. 15 illustrates a cross-sectional view of a light emitting device according to one or more embodiments;

FIG. 16 illustrates a cross-sectional view of a light emitting device according to one or more embodiments;

FIG. 17 illustrates a cross-sectional view of a light emitting device according to one or more embodiments; and

FIG. 18 illustrates a top plan view of a light emitting device according to one or more embodiments.

### DETAILED DESCRIPTION

Before describing several exemplary embodiments of the disclosure, it is to be understood that the disclosure is not limited to the details of construction or process steps set forth in the following description. The disclosure is capable of other embodiments and of being practiced or being carried out in various ways.

The term “monolithic light emitting diode (LED) array” refers to a multitude of LED chips rigidly mounted to a substrate. Emitters are arranged in an X,Y addressable matrix and may have separately addressable connection. The spacing between light emitting areas can vary in size from 10 μm in width. The array sizes and shapes can vary to meet specific requirements.

The term “package” and “packaged” and the like refers to a plastic casing that carries an LED chip and phosphor. The LED chip is the semiconductor material that emits light (blue light), and the phosphor material converts some of this light into green and red wavelengths. An “unpackaged light-emitting diode (LED)” as used herein refers to an LED chip and phosphor arrangement that does not have a protective package.

In the following description, numerous specific details, such as specific materials, chemistries, dimensions of the elements, etc. are set forth in order to provide thorough understanding of one or more of the embodiments of the present disclosure. It will be apparent, however, to one of ordinary skill in the art that the one or more embodiments of the present disclosure may be practiced without these specific details. In other instances, LED fabrication processes, techniques, materials, equipment, etc., have not been descried in great details to avoid unnecessarily obscuring of this description. Those of ordinary skill in the art, with the included description, will be able to implement appropriate functionality without undue experimentation.

While certain exemplary embodiments of the disclosure are described and shown in the accompanying drawings, it is to be understood that such embodiments are merely illustrative and not restrictive of the current disclosure, and that this disclosure is not restricted to the specific constructions and arrangements shown and described because modifications may occur to those ordinarily skilled in the art.

Embodiments described herein provide a monolithic array of unpackaged LED. In one or more embodiments, the monolithic array of unpackaged LED is attached to each other by a highly reflective coating material. Such a monolithic device later can be later mounted to an appropriate printed circuit board (PCB) or other substrate. In one or more embodiments, to control light cross talk between the LED, a thin layer of light absorbing material is inserted. In one or more embodiments, the distance between LED light emitting areas can be less than or equal to 120 μm.

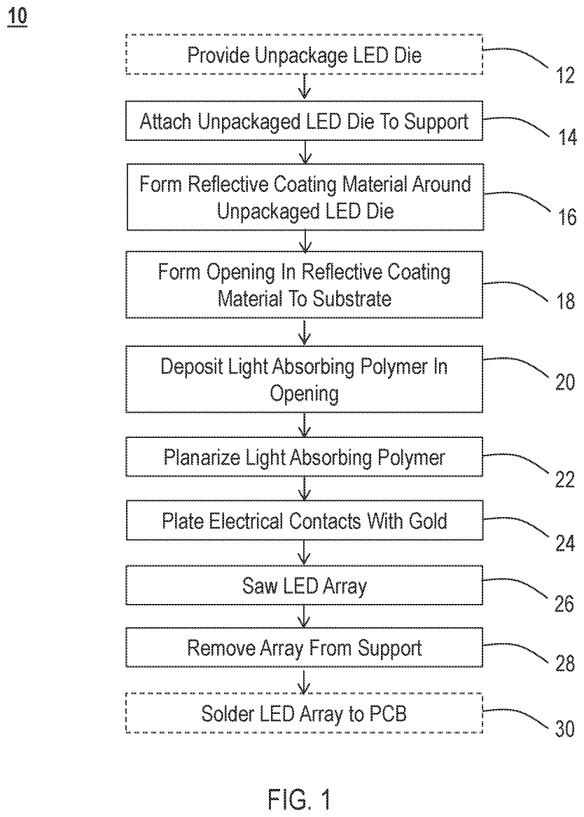

FIG. 1 depicts a flow diagram of a method 10 of manufacturing a light emitting device in accordance with one or more embodiments of the present disclosure. With reference to FIG. 1, in one or more embodiments, the method begins at operation 12 where an unpackaged LED is provided. As used in this specification and the appended claims, the term “provided” means that the unpackaged LED is made available for processing (e.g., positioned in a processing chamber). At operation 14, the unpackaged LED is attached to a support. A reflective coating material is formed around the unpackaged LED at operation 16. At operation 18, an opening in the reflective coating material is formed. At operation 20, a light absorbing material is deposited in the opening. At operation 22, the light absorbing material and reflective layer are planarized to open the metal contacts. At operation 24, the electrical contacts are plated with gold (Au). The light absorbing material is sawn through at operation 26. At operation 28, the LED array is removed from the support. At operation 30, the LED array is soldered to a printed circuit board (PCB) or other substrate.

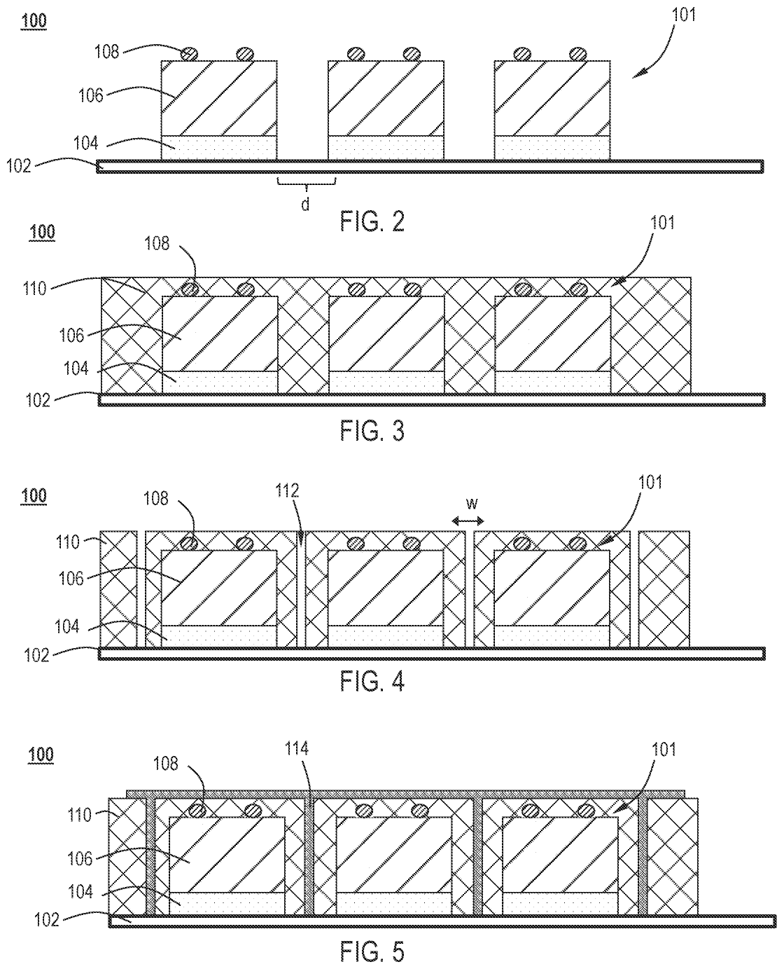

FIGS. 2 to 9 illustrate views of an LED array 100 following the process flow illustrated for the method 10 of FIG. 1. FIGS. 2 to 8 are cross-section views of the light emitting device, and FIG. 9 is a top plan view of the light emitting device.

With reference to FIGS. 1 and 2, in one or more embodiments, the method begins at operation 12 where at least one unpackaged LED 101 is provided. As used in this regard, the term “provided” means that the unpackaged LED 101 is placed into a position or environment for further processing. In one or more embodiments, the unpackaged LED 101 includes at least one electrical contact 108, a transparent substrate 106, and a light converting layer 104.

The transparent substrate 106 may comprise any suitable substrate known to the skilled artisan. In one or more embodiments, the transparent substrate comprises one or more of sapphire, silicon carbide, silicon (Si), quartz, magnesium oxide (MgO), zinc oxide (ZnO), spinel, and the like. In one or more embodiments, the substrate is not patterned prior to the growth of the Epi-layer. Thus, in some embodiments, the substrate 106 is not patterned and can be considered to be flat or substantially flat. In other embodiments, the substrate 106 is patterned, e.g., patterned sapphire substrate (PSS).

In some embodiments the transparent substrate 106 can support an epitaxially grown or deposited semiconductor N-layer. A semiconductor p-layer can then be sequentially grown or deposited on the N-layer, forming an active region at the junction between layers. Semiconductor materials capable of forming high-brightness light emitting devices can include, but are not limited to, Group III-V semiconductors, particularly binary, ternary, and quaternary alloys of gallium, aluminum, indium, and nitrogen, also referred to as III-V nitride materials. In some embodiments, the III-nitride material comprises one or more of gallium (Ga), aluminum (Al), and indium (In). Thus, in some embodiments, the semiconductor layer comprises one or more of gallium nitride (GaN), aluminum nitride (AlN), indium nitride (InN), gallium aluminum nitride (GaAlN), gallium indium nitride (GaInN), aluminum gallium nitride (AlGaN), aluminum indium nitride (AlInN), indium gallium nitride (InGaN), indium aluminum nitride (InAlN), and the like. In one or more specific embodiments, the semiconductor layer comprises gallium nitride and is an n-type layer.

It will be appreciated by one of skill in the art that the substrate 106 may include one or more material layers (e.g., Ill-nitride, and the like), vias, and the like thereon. In one or more embodiments, the substrate may include semiconductor layers including an N-type layer, an active layer, and a P-type layer that is capable of emitting light when electrically powered.

In one or more embodiments, an electrical contact 108 is on the top surface of the substrate 106. The electrical contact 108 may comprise any suitable contact known to the skilled artisan. For example, in some embodiments, the electrical contact 108 may comprise one or more of a p-type contact or an n-type contact. In some embodiments, the electrical contact 108 includes a metal selected from one or more of copper (Cu), nickel (Ni), aluminum (Al), and gold (Au).

In some embodiments, the substrate 106 is on a light converting layer 104, the light converting layer 104 on an opposing surface of the substrate 106 from the electrical contact 108. The light converting layer 104 absorbs energy, converting an entering wavelength to a lower-energy higher wavelength, and scatter light. The light converting layer 104 may comprise any suitable material known to the skilled artisan. In one or more embodiments, the light converting layer 104 comprises phosphor. As used herein, the term “phosphor” refers to a solid material which emits visible light when exposed to radiation from a deep blue, ultra-violet, or electron beam source. Through careful tuning of the phosphor composition and structure, the spectral content of the emitted light can be tailored to meet certain performance criteria. In some embodiments, the phosphor is selected from a ceramic phosphor plate or phosphor in silicone.

At operation 14, a plurality of unpackaged LED 101 is attached to support 102. In one or more embodiments, the support 102 can comprise any suitable support material. In one or more specific embodiments, the support 102 is a carrier tape. The tape can be dual side coated, such as one side having a pressure sensitive adhesive and another has a thermal release or UV sensitive adhesive which allows, when exposed to UV light, to release form the solid substrate. The unpackaged LED 101 are spaced a distance, d, in a range of from 10 μm to 500 μm apart from an adjacent unpackaged LED 101. In other embodiments, the unpackaged LED 101 are spaced at least about 120 μm apart from an adjacent unpackaged LED 101.

Referring to FIG. 3, at operation 16 of method 10, the array 100 is then molded with a reflective coating material 110. In one or more embodiments, the reflective coating material 110 is formed around the unpackaged LED 101. The reflective coating material 110 interacts with all surfaces of the unpackaged LED 101 except for the surface of the unpackaged LED die 110 that is on the support 102. In one or more embodiments, the reflective coating material 110 is highly reflective having a reflectance in a range of from 90% to 99%, or in a range of from 90% to 98%, or in a range of from 91% to 97%, or in a range of from 92% to 96%, or in a range of from 93% to 95%.

The reflective coating material 110 may comprise any suitable material known to the skilled artisan. In one or more embodiments, the reflective coating material is selected from one or more of silicone, titanium oxide (TiO₂), zirconium oxide (ZrO₂), aluminum oxide (Al₂O₃), or other metal oxides.

The reflective coating material 110 may have any suitable thickness. In one or more embodiments, the reflective coating material 110 may have a thickness in a range of from 40 μm to 60 μm.

In one or more embodiments, the reflective coating material 110 serves not only to reflect light, but also serves as a structure element of the array 100 by holding the unpackaged LED 101 of the array together. Thus, in one or more embodiments, the unpackaged light-emitting diode (LED) 101 in the light-emitting diode (LED) array 101 are fixed in place by the reflective coating material 110.

In some embodiments, the reflective coating material 110 includes a thin vertical layer of light absorbing material. Without intending to be bound by theory, it is thought that the presence of the light absorbing material in the reflective coating material 110 will improve optical crosstalk between the LED die.

With reference to FIG. 4, at operation 18, an opening 112 is formed in the reflective coating. In one or more embodiments, an opening 112 in the reflective coating material is formed between each of the unpackaged light-emitting diode (LED) 101. As illustrated in FIG. 4, the opening 112 extends completely through the reflective coating material 110 to the support 102. The opening 112 may be formed by any suitable means known to the skilled artisan. In one or more embodiments, the reflective coating material 110 is sawed with a thin blade to create the opening 112 between the molded unpackaged light-emitting diode (LED) 110 of the array 100. The opening 112 has a width, w, in a range of from 1 μm to 30 μm, or in a range of from 5 μm to 25 μm, or in a range of from 10 μm to 25 μm.

Referring to FIG. 5, at operation 20, a light absorbing material 114 is deposited in the opening 112. The light absorbing material 114 may comprise any suitable material known to the skilled artisan. In one or more embodiments, the light absorbing material 114 comprises one or more of silicone, carbon, and a metal material.

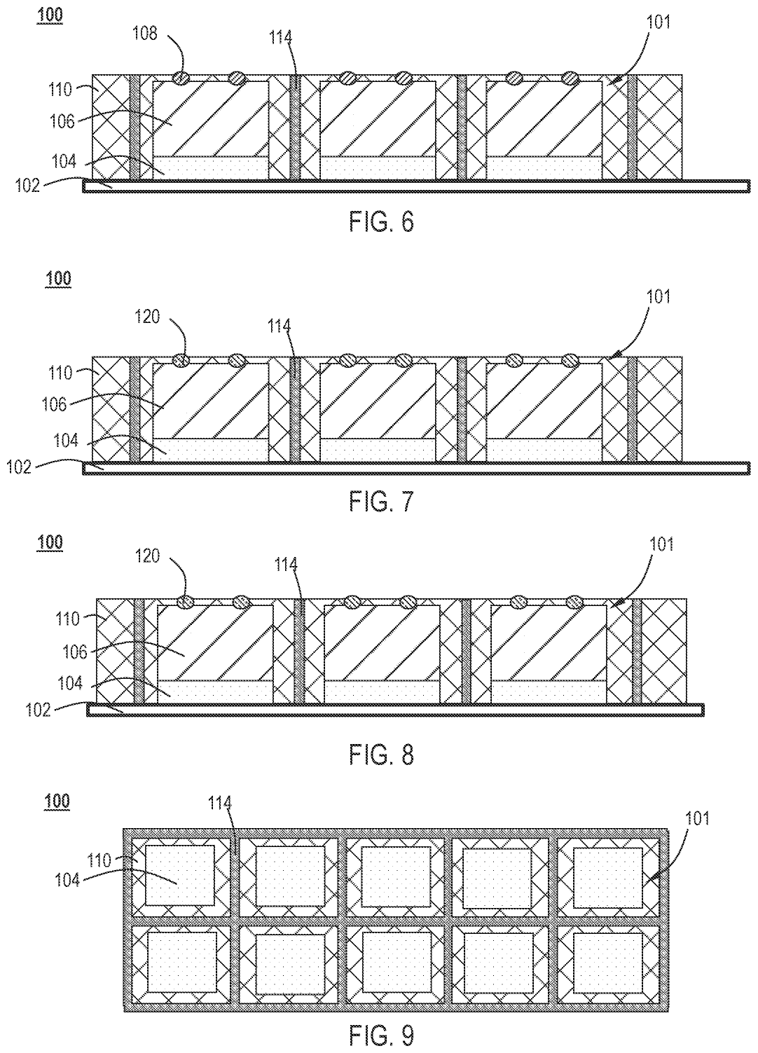

As illustrated in FIG. 6, at operation 22, the array 100 is planarized or ground to remove a portion of the light absorbing material 114 from a top surface of the array 100. The light absorbing material 114 may be removed by any suitable means including, but not limited to chemical mechanical planarization (CMP) and grinding.

At operation 24, as illustrated in FIG. 7, at operation 24, the electrical contacts 108 are plated with gold (Au) through an immersion process to form gold plated electrical contacts 120. Gold (Au) plating is done by electroless nickel immersion gold (ENIG). It comprises electroless nickel plating, which is covered with a thin layer of immersion gold. In immersion gold, the gold layer is generated on the nickel layer through displacement. It continues until the generated gold layer is covered with nickel. This is why gold layer is very thin. This layer protects nickel from oxidation.

With reference to FIG. 8, at operation 26 the array is sawed to decrease the length of the support 102.

Referring to FIG. 9, at operation 28, the array 100 with the unpackaged LED 101 is removed from the support 102. A top plane view of the array 100 shows the light converting layer 104 surrounded by the reflective coating material 110 and separated by the light absorbing material 114.

In one or more unillustrated embodiments, at operation 30, the array 100 may be soldered to a printed circuit board (PCB) or other substrate.

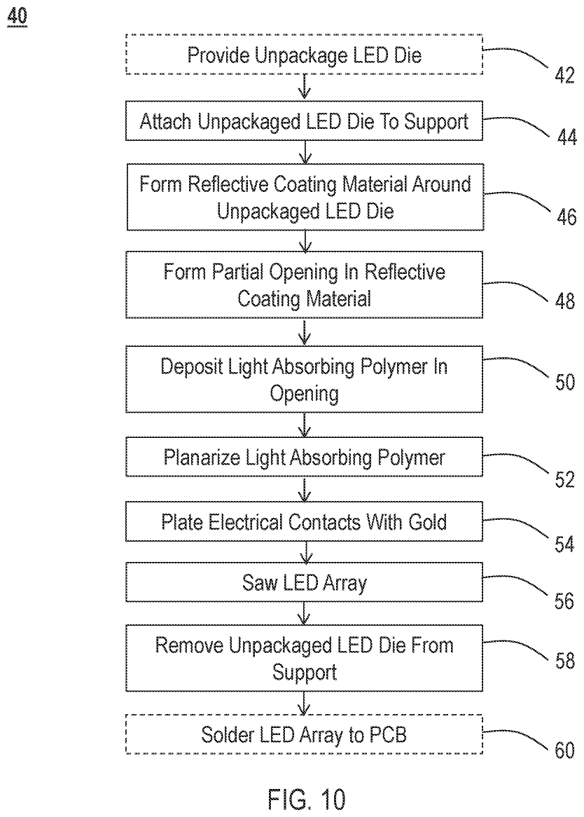

FIG. 10 depicts a flow diagram of a method 40 of manufacturing a light emitting diode (LED) device in accordance with one or more alternative embodiments of the present disclosure. With reference to FIG. 10, in one or more embodiments, the method 40 begins at operation 42 where an unpackaged LED is provided. At operation 44, the unpackaged LED die is attached to a support. A reflective coating material is formed around the unpackaged LED die at operation 46. At operation 48, an opening in the reflective coating material is partially formed. At operation 50, a light absorbing material is deposited in the opening. At operation 52, the excess of the light absorbing material and light reflective materials are planarized away, such as to open the electrical contacts of the LEDs. At operation 54, the electrical contacts are plated with gold (Au). At operation 56, the light absorbing material is sawn through. At operation 58, the LED array is removed from the support. At operation 60, the LED array is soldered to a printed circuit board (PCB) or other substrate.

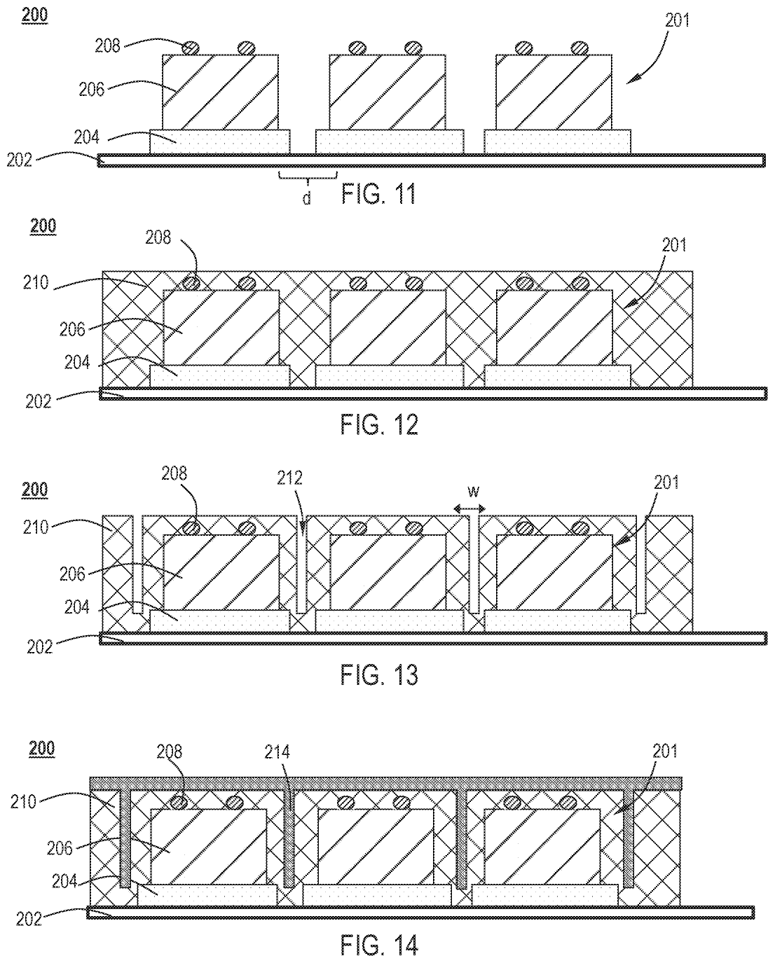

FIGS. 11 to 18 illustrate views of an LED array 200 following the process flow illustrated for the method 40 of FIG. 10. FIGS. 11 to 17 are cross-section views of the LED device, and FIG. 18 is a top plan view of the LED device.

With reference to FIGS. 10 and 11, in one or more embodiments, the method begins at operation 42 where at least one unpackaged LED die 201 is provided. In one or more embodiments, the unpackaged LED die 201 includes at least one electrical contact 208, a transparent substrate 206, and a light converting layer 204.

As described above with respect to FIG. 2, the transparent substrate 206 may comprise any suitable substrate known to the skilled artisan. In one or more embodiments, the transparent substrate comprises one or more of sapphire, silicon carbide, silicon (Si), quartz, magnesium oxide (MgO), zinc oxide (ZnO), spinel, and the like. In one or more embodiments, the substrate is not patterned prior to the growth of the Epi-layer. Thus, in some embodiments, the substrate 206 is not patterned and can be considered to be flat or substantially flat. In other embodiments, the substrate 206 is patterned, e.g., patterned sapphire substrate (PSS).

In some embodiments the transparent substrate 206 can support an epitaxially grown or deposited semiconductor N-layer. A semiconductor p-layer can then be sequentially grown or deposited on the N-layer, forming an active region at the junction between layers. Semiconductor materials capable of forming high-brightness light emitting devices can include, but are not limited to, Group III-V semiconductors, particularly binary, ternary, and quaternary alloys of gallium, aluminum, indium, and nitrogen, also referred to as III-V nitride materials. In some embodiments, the III-V nitride material comprises one or more of gallium (Ga), aluminum (Al), and indium (In). Thus, in some embodiments, the semiconductor layer comprises one or more of gallium nitride (GaN), aluminum nitride (AlN), indium nitride (InN), gallium aluminum nitride (GaAlN), gallium indium nitride (GaInN), aluminum gallium nitride (AlGaN), aluminum indium nitride (AlInN), indium gallium nitride (InGaN), indium aluminum nitride (InAlN), and the like. In one or more specific embodiments, the semiconductor layer comprises gallium nitride and is an n-type layer.

In one or more embodiments, the substrate 206 may include one or more material layers (e.g., III-V nitride, and the like), vias, and the like thereon. In one or more embodiments, the substrate may include semiconductor layers including an N-type layer, an active layer, and a P-type layer that is capable of emitting light when electrically powered.

In one or more embodiments, an electrical contact 208 is on the top surface of the substrate 206. The electrical contact 208 may comprise any suitable contact known to the skilled artisan. For example, in some embodiments, the electrical contact 208 may comprise one or more of a p-type contact or an n-type contact. In some embodiments, the electrical contact 208 includes a metal selected from one or more of copper (Cu), nickel (Ni), aluminum (Al), and gold (Au).

In some embodiments, the substrate 206 is on a light converting layer 204, the light converting layer 204 on an opposing surface of the substrate 206 from the electrical contact 208. The light converting layer 24 absorbs energy, converting an entering wavelength to a lower-energy higher wavelength, and scatter light. The light converting layer 204 may comprise any suitable material known to the skilled artisan. In one or more embodiments, the light converting layer 204 comprises phosphor.

At operation 44, a plurality of unpackaged LED 201 is attached to support 202. In one or more embodiments, the support 202 comprises a carrier tape. The tape can be dual side coated, such as one side having a pressure sensitive adhesive and another has a thermal release or UV sensitive adhesive which allows, when exposed to UV light, to release form the solid substrate. The unpackaged LED 201 are spaced a distance, d, in a range of from 10 μm to 500 μm apart from an adjacent unpackaged LED 201. In other embodiments, the unpackaged LED 201 are spaced at least about 120 μm apparat from an adjacent unpackaged LED 201.

Referring to FIG. 12, at operation 46 of method 40, the array 200 is then molded with a reflective coating material 210. In one or more embodiments, the reflective coating material 210 is formed around the unpackaged LED 201. The reflective coating material 210 interacts with all surfaces of the unpackaged LED 201 except for the surface of the unpackaged LED 210 that is on the support 202. In one or more embodiments, the reflective coating material 210 is highly reflective having a reflectance in a range of from 90% to 99%, or in a range of from 90% to 98%, or in a range of from 91% to 97%, or in a range of from 92% to 96%, or in a range of from 93% to 95%.

The reflective coating material 210 may comprise any suitable material known to the skilled artisan. In one or more embodiments, the reflective coating material is selected from one or more of silicone, titanium oxide (TiO₂), zirconium oxide (ZrO₂), aluminum oxide (Al₂O₃), or other metal oxides.

The reflective coating material 210 may have any suitable thickness. In one or more embodiments, the reflective coating material 210 may have a thickness in a range of from 40 μm to 60 μm.

In one or more embodiments, the reflective coating material 210 serves not only to reflect light, but also serves as a structure element of the array 200 by holding the unpackaged light-emitting diode (LED) 201 of the array together. Thus, in one or more embodiments, the unpackaged light-emitting diode (LED) 201 in the light-emitting diode (LED) array 201 are fixed in place by the reflective coating material 210.

In some embodiments, the reflective coating material 210 includes a thin vertical layer of light absorbing material. Without intending to be bound by theory, it is thought that the presence of the light absorbing material in the reflective coating material 210 will improve optical crosstalk between the LED die.

With reference to FIG. 13, at operation 48, an opening 212 is formed in the reflective coating 210. In one or more embodiments, an opening 212 in the reflective coating material is formed between each of the unpackaged light-emitting diode (LED) 201. As illustrated in FIG. 13, the opening 212 does not extend completely through the reflective coating material 210 to the support 202. Accordingly, in one or more embodiments, the opening 212 extends only partially through the thickness of the reflective coating material 210. The opening 212 may be formed by any suitable means known to the skilled artisan. In one or more embodiments, the reflective coating material 210 is sawed with a thin blade to create the opening 212 between the molded unpackaged light-emitting diode (LED) 210 of the array 200. The opening 212 has a width, w, in a range of from 1 μm to 30 μm, or in a range of from 5 μm to 25 μm, or in a range of from 10 μm to 25 μm.

Referring to FIG. 14, at operation 50, a light absorbing material 214 is deposited in the opening 212. The light absorbing material 214 may comprise any suitable material known to the skilled artisan. In one or more embodiments, the light absorbing material 214 comprises one or more of silicone, carbon, and a metal material.

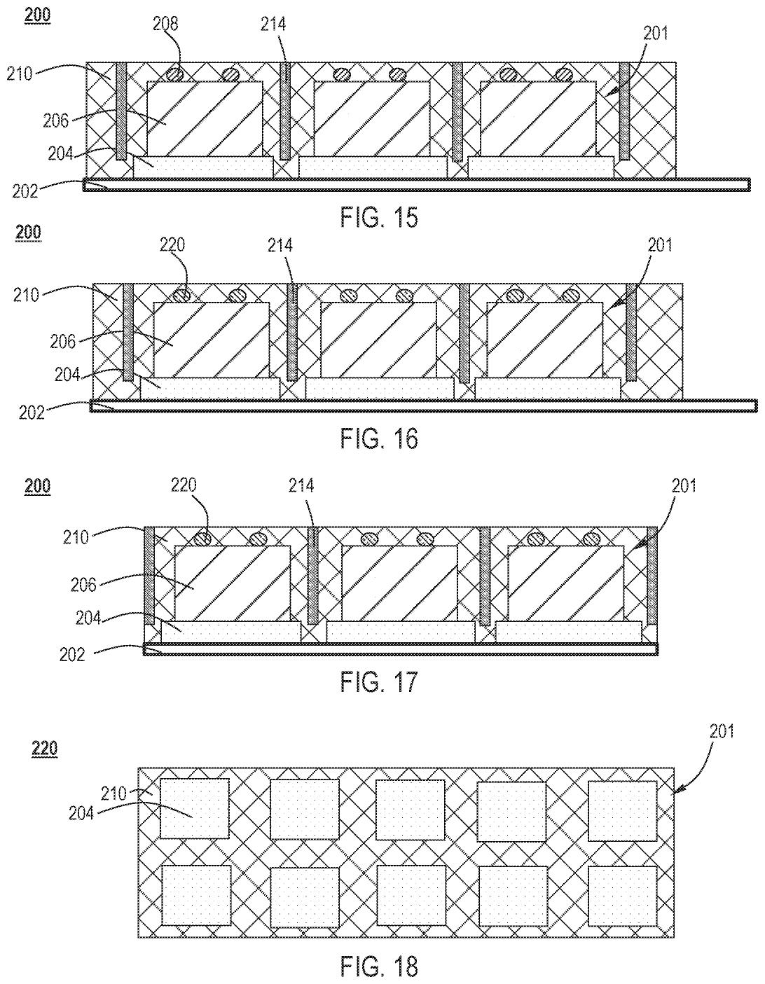

As illustrated in FIG. 15, at operation 52, the array 200 is planarized or ground to remove a portion of the light absorbing material 214 from a top surface of the array 200. The light absorbing material 214 may be removed by any suitable means including, but not limited to chemical mechanical planarization (CMP) and grinding.

At operation 54, as illustrated in FIG. 16, electrical contacts are plated with gold (Au) through an immersion process to form gold plated electrical contacts 220. Gold (Au) plating is done by electroless nickel immersion gold (ENIG). It comprises electroless nickel plating, which is covered with a thin layer of immersion gold. In immersion gold, the gold layer is generated on the nickel layer through displacement. It continues until the generated gold layer is covered with nickel. With reference to FIG. 17, at operation 56 the array is sawed to decrease the length of the support 202.

Referring to FIG. 18, at operation 58, the array 200 with the unpackaged LED 201 is removed from the support 202. A top plane view of the array 200 shows the light converting layer 204 surrounded by the reflective coating material 210 and partially separated by the light absorbing material 214.

In one or more unillustrated embodiments, at operation 60, the array 200 may be soldered to a printed circuit board (PCB).

### Embodiments

Various embodiments are listed below. It will be understood that the embodiments listed below may be combined with all aspects and other embodiments in accordance with the scope of the invention.

Embodiment (a). A light-emitting device comprising a plurality of unpackaged light-emitting diodes arranged in a grid, each of the unpackaged light-emitting diodes surrounded by a reflective coating material, where each of the unpackaged light-emitting diode of the grid is fixed in place by the reflective coating material.

Embodiment (b). The LED device of embodiment (a), further comprising a light absorbing material separating the plurality of unpackaged light-emitting diodes.

Embodiment (c). The LED device of embodiment (a) to embodiment (b), wherein the light absorbing material partially separates the plurality of unpackaged light-emitting diodes.

Embodiment (d). The LED device of embodiment (a) to embodiment (c), wherein the light absorbing material partially separates the plurality of unpackaged light-emitting diodes.

Embodiment (e). The LED device of embodiment (a) to embodiment (d), wherein each of the plurality of unpackaged light-emitting diodes comprise at least one electrical contact, a sapphire substrate, and a light converting layer.

Embodiment (f). The LED device of embodiment (a) to embodiment (e), further comprising a printed circuit board (PCB), wherein the LED array is mounted on the PCB.

Embodiment (g). The LED device of embodiment (a) to embodiment (f), wherein the light converting layer comprises phosphor and wherein the at least one electrical contact comprises one or more of copper (Cu), nickel (Ni), aluminum (Al), and gold (Au).

Embodiment (h). The LED device of embodiment (a) to embodiment (g), wherein the phosphor is selected from a ceramic phosphor plate or phosphor in silicone.

Embodiment (l). The LED device of embodiment (a) to embodiment (h), wherein the reflective coating material comprises one or more of silicone, silicon dioxide (SiO₂), titanium oxide (TiO₂), zirconium oxide (ZrO₂), aluminum oxide (Al₂O₃), and other metal oxides.

Embodiment (j). The LED device of embodiment (a) to embodiment (l), wherein the light absorbing material comprises one or more of silicone, carbon particles, or a metal material.

Embodiment (k). The LED device of embodiment (a) to embodiment (j), wherein each of the plurality of unpackaged light-emitting diode (LED) die are separated from an adjacent plurality of unpackaged light-emitting diode (LED) die by a distance in a range of about 10 μm to about 500 μm.

Embodiment (l). The LED device of embodiment (a) to embodiment (k), wherein the reflective coating material has a reflectance in a range of from 80% to 100%.

Embodiment (m). The LED device of embodiment (a) to embodiment (l), wherein the reflective coating material as a thickness in a range of from 10 μm to 500 μm.

Embodiment (n). A method of manufacturing a light-emitting diode (LED) device, the method comprising: attaching a plurality of unpackaged light-emitting diodes to a support material; forming a reflective coating material around each of the plurality of unpackaged light-emitting diodes; forming an opening in the reflective coating material between each of the plurality of unpackaged light-emitting diodes, the opening extending through the reflective coating material; depositing a light absorbing material in the opening; and removing the plurality of unpackaged light-emitting diodes from the support material to form a light-emitting diode (LED) array.

Embodiment (o). The method of embodiment (n), further comprising planarizing the light absorbing material.

Embodiment (p). The method of embodiment (n) to embodiment (o), further comprising sawing the light-emitting diode (LED) array.

Embodiment (q). The method of embodiment (n) to embodiment (p), further comprising soldering the light-emitting diode (LED) array to a printed circuit board (PCB).

Embodiment (r). The method of embodiment (n) to embodiment (q), wherein the opening extends partially through the reflective coating material.

The use of the terms “a” and “an” and “the” and similar referents in the context of describing the materials and methods discussed herein (especially in the context of the following claims) are to be construed to cover both the singular and the plural, unless otherwise indicated herein or clearly contradicted by context. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate the materials and methods and does not pose a limitation on the scope unless otherwise claimed. No language in the specification should be construed as indicating any non-claimed element as essential to the practice of the disclosed materials and methods.

Reference throughout this specification to “one embodiment,” “certain embodiments,” “one or more embodiments” or “an embodiment” means that a particular feature, structure, material, or characteristic described in connection with the embodiment is included in at least one embodiment of the disclosure. Thus, the appearances of the phrases such as “in one or more embodiments,” “in certain embodiments,” “in one embodiment” or “in an embodiment” in various places throughout this specification are not necessarily referring to the same embodiment of the disclosure. In one or more embodiments, the particular features, structures, materials, or characteristics are combined in any suitable manner.

Although the disclosure herein has been described with reference to particular embodiments, it is to be understood that these embodiments are merely illustrative of the principles and applications of the present disclosure. It will be apparent to those skilled in the art that various modifications and variations can be made to the method and apparatus of the present disclosure without departing from the spirit and scope of the disclosure. Thus, it is intended that the present disclosure include modifications and variations that are within the scope of the appended claims and their equivalents.

What is claimed is:

1. A light-emitting device comprising a plurality of unpackaged light-emitting diodes arranged in a grid, each of the unpackaged light-emitting diodes surrounded by a reflective coating material, where each of the unpackaged light-emitting diode of the grid fixed in place by the reflective coating material.

2. The light-emitting device of claim 1, further including a layer of light absorbing material separating the plurality of unpackaged light-emitting diodes.

3. The light-emitting device of claim 2, wherein the light absorbing material partially separates the plurality of unpackaged light-emitting diodes.

4. The light-emitting device of claim 1, wherein each of the plurality of unpackaged light-emitting diodes comprise at least one electrical contact, a sapphire substrate, and a light converting layer.

5. The light-emitting device of claim 1, further comprising a printed circuit board (PCB), wherein the LED array is mounted on the PCB.

6. The light-emitting device of claim 4, wherein the light converting layer comprises phosphor and wherein the at least one electrical contact comprises one or more of copper (Cu), nickel (Ni), aluminum (Al), and gold (Au).

7. The light-emitting device of claim 6, wherein the phosphor is selected from a ceramic phosphor plate or phosphor in silicone.

8. The light-emitting device of claim 1, wherein the reflective coating material comprises one or more of silicone, silicon dioxide (SiO₂), titanium oxide (TiO₂), zirconium oxide (ZrO₂), aluminum oxide (Al₂O₃), and other metal oxides.

9. The light-emitting device of claim 1, wherein the light absorbing material comprises of one or more of silicone, carbon particles, or a metal material.

10. The light-emitting device of claim 1, wherein each of the plurality of unpackaged light-emitting diode (LED) die are separated from an adjacent plurality of unpackaged light-emitting diode (LED) die by a distance in a range of about 10 μm to about 500 μm.

11. The light-emitting device of claim 1, wherein the reflective coating material has a reflectance in a range of from 80% to 100%.

12. The light-emitting device of claim 1, wherein the reflective coating material as a thickness in a range of from 10 μm to 500 μm.

13. A method of manufacturing a light-emitting diode (LED) device, the method comprising:
attaching a plurality of unpackaged light-emitting diodes to a support material;
forming a reflective coating material around each of the plurality of unpackaged light-emitting diodes;
forming an opening in the reflective coating material between each of the plurality of unpackaged light-emitting diodes, the opening extending through the reflective coating material;
depositing a light absorbing material in the opening; and
removing the plurality of unpackaged light-emitting diodes from the support material to form a light-emitting diode (LED) array.

14. The method of claim 13, further comprising planarizing the light absorbing material.

15. The method of claim 14, further comprising sawing the light-emitting diode (LED) array.

16. The method of claim 14, further comprising soldering the light-emitting diode (LED) array to a printed circuit board (PCB).

17. The method of claim 15, wherein the opening extends partially through the reflective coating material.
